(19) United States
(12) Patent Application Publication
(10) Pub. No.: US 2025/0239574 A1
(43) Pub. Date: Jul. 24, 2025

(54) FRONT-TO-FRONT BONDING IN A STACKED MEMORY SYSTEM

(71) Applicant: Micron Technology, Inc., Boise, ID (US)

(72) Inventors: Bharat Bhushan, Boise, ID (US); Kunal R. Parekh, Boise, ID (US); Akshay N. Singh, Boise, ID (US)

(21) Appl. No.: 19/019,139

(22) Filed: Jan. 13, 2025

Related U.S. Application Data
(60) Provisional application No. 63/623,113, filed on Jan. 19, 2024.

(51) Int. Cl. H01L 25/16; H01L 21/48; H01L 21/56; H01L 23/00; H01L 23/48; H10B 80/00; H10D 80/30

(52) U.S. Cl. CPC H01L 25/16; H01L 21/486; H01L 21/56; H01L 23/481; H01L 24/04; H01L 24/05; H01L 24/08; H01L 24/16; H01L 24/80; H10B 80/00; H10D 80/30; H01L 24/96; H01L 24/97; H01L 2224/0401; H01L 2224/05624; H01L 2224/08145; H01L 2224/16225; H01L 2224/80006; H01L 2224/80895; H01L 2224/80896; H01L 2224/96; H01L 2224/97; H01L 2225/06517; H01L 2225/06544; H01L 2924/1431; H01L 2924/14361

(57) ABSTRACT

Methods, systems, and devices for front-to-front bonding in a stacked memory system are described. The stacked memory system may include a package substrate and a volatile memory die with a front side. The stacked memory system may also include a logic die with a front side that is bonded with the front side of the volatile memory die. The back side of the stacked memory system may be coupled with a conductive bump that in turn is coupled with the package substrate.

### CROSS REFERENCE

The present Application for Patent claims the benefit of U.S. Provisional Patent Application No. 63/623,113 by BHUSHAN et al., entitled “FRONT-TO-FRONT BONDING IN A STACKED MEMORY SYSTEM,” filed Jan. 19, 2024, assigned to the assignee hereof, and expressly incorporated by reference in its entirety herein.

### TECHNICAL FIELD

The following relates to one or more semiconductor systems, including front-to-front bonding in a stacked memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. A semiconductor die (e.g., wafer) that is part of a stacked memory system may have a front side and a back side. The front side of a die (e.g., wafer) may refer to the side of the die (e.g., wafer) that is doped during manufacturing to form various components such as transistors and may be the side from which back-end-of-line (BEOL) circuitry is formed. The back side of a die (e.g., wafer) may refer to the side of the die (e.g., wafer) that is opposite of the front side. To form a stacked memory system, it may be desirable to bond a memory die with a logic wafer using a high temperature (e.g., 350° C.). But use of such a high temperature may deleteriously affect other materials used in the manufacturing process or included in the stacked memory system.

### BRIEF DESCRIPTION OF THE DRAWINGS

FIG. 1 shows an example of a system that supports front-to-front bonding in a stacked memory system in accordance with examples as disclosed herein.

FIG. 2 shows an example of a system that supports front-to-front bonding in a stacked memory system in accordance with examples as disclosed herein.

FIG. 3 shows a block diagram of a stacked memory system that supports front-to-front bonding in accordance with examples as disclosed herein.

FIG. 4 shows a cross-section view of a stacked memory system that supports front-to-front bonding in accordance with examples as disclosed herein.

FIG. 5 shows a block diagram of a stacked memory system that supports front-to-front bonding in accordance with examples as disclosed herein.

FIG. 6 shows a cross-section view of a stacked memory system that supports front-to-front bonding in accordance with examples as disclosed herein.

FIGS. 7A through 7G show examples of a stacked memory system at various manufacturing stages that support front-to-front bonding in accordance with examples as disclosed herein.

FIGS. 8A through 8G show examples of a stacked memory system at various manufacturing stages that support front-to-front bonding in accordance with examples as disclosed herein.

FIG. 9 shows a block diagram of a manufacturing system that supports front-to-front bonding in a stacked memory system in accordance with examples as disclosed herein.

FIG. 10 shows a flowchart illustrating a method or methods that support front-to-front bonding in a stacked memory system in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be referred to as a stacked memory system and may be implemented as part of a high bandwidth memory (HBM) system or a coupled dynamic random access memory (DRAM) system, among other examples, and may support solutions for memory-centric logic, such as graphics processing units (GPUs), among other implementations.

A semiconductor die (e.g., a part of a wafer) that is part of a stacked memory system may have a front side and a back side. Similarly, a wafer having multiple semiconductor dies, which are not singulated, may also have a front side and a back side. The front side of a die/wafer may refer to the side of the die/wafer that is doped during manufacturing to form various components such as transistors and may be the side from which back-end-of-line (BEOL) circuitry is formed. The back side of a die/wafer may refer to the side of the die/wafer that is opposite of the front side.

To form a stacked system using copper hybrid bonding with a threshold pad dishing (e.g., at least 3 um pad dishing), it may be desirable to bond a die with a wafer using a high temperature such as 350° C. This is similarly desired in a stacked memory system. However, such use of high temperature may deleteriously affect other materials used in the manufacturing process. For example, in the memory stacked system, the high temperature may exceed the thermal budget of a temporary bonding material that is applied to stacked memory system before bonding the front side of the memory die with a back side of the logic wafer, a phenomenon which may destabilize the stacked memory system, or hinder or prevent its manufacture altogether. As another example, the high temperature may exceed the thermal budget of conductive bumps applied to the stacked memory system (e.g., to the front side of the logic wafer) before bonding the front side of the memory die with the back side of the logic wafer, a phenomenon which may compromise the integrity of the conductive bumps.

According to the techniques described herein, a stacked memory system may be manufactured using a high-temperature bonding technique (e.g., a bonding technique that uses temperatures above 300° C.) —without compromising other steps of the manufacturing process—by bonding the front side of the memory die with the front side of the logic die. Such a technique may allow other steps of the manufacturing process (e.g., steps that involve materials that are sensitive to high temperatures) to be performed after use of the high-temperature bonding technique. Thus, application of high temperatures to temperature-sensitive materials of the stacked memory system (or temperature-sensitive materials involved in the manufacturing process) may be avoided even though a high-temperature bonding technique is used to bond the memory die with the logic wafer.

In addition to applicability in memory systems as described herein, techniques for front-to-front, high-temperature bonding may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds and reliability (e.g., due to higher-quality bonding between dies/wafers), which may decrease processing or latency times, improve response times, or otherwise improve user experience, among other benefits.

In addition to applicability in memory systems as described herein, techniques for front-to-front, high-temperature bonding may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by eliminating production processes associated with other bonding techniques, which may result in lowered production emissions, among other benefits. Implementing the techniques described herein may improve the impact related to electronic devices by increasing the yield relative to production processes associated with other bonding techniques (e.g., as such bonding techniques/production processes are either incapable of being used at such high temperatures or may result in excessive wastage due to fusion bonding to temporary bond with silicon).

In addition to applicability in memory systems as described herein, techniques for front-to-front, high-temperature bonding may be generally implemented to support increased connectivity of electronic systems. Particularly, front-to-front configurations may reduce the delays between two dies. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving connectivity between devices (e.g., due to higher-quality bonding between dies/wafers), thereby improving data transfer between devices and enabling increased communications between devices), among other benefits.

Features of the disclosure are illustrated and described in the context of systems and architectures. Features of the disclosure are further illustrated and described in the context of stacked memory systems and flowcharts.

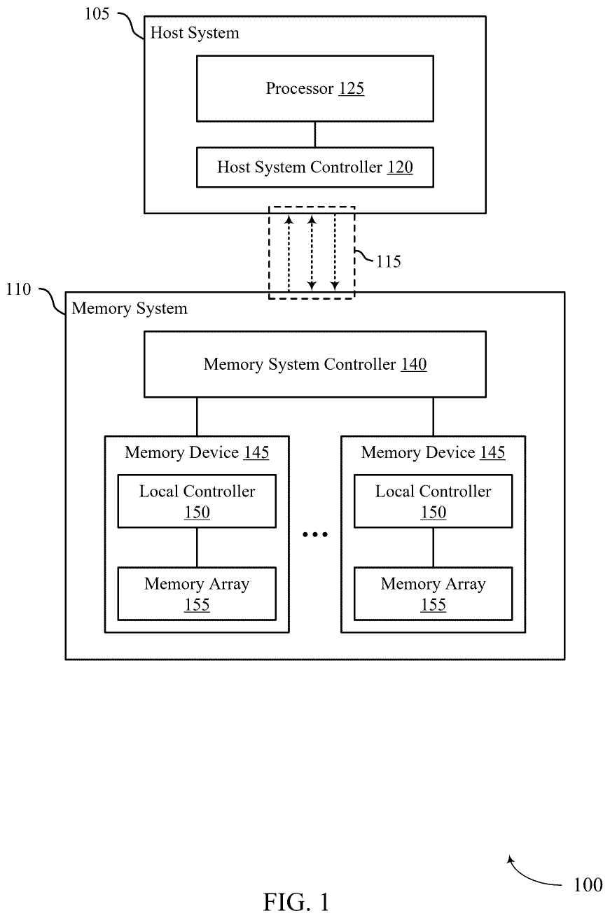

FIG. 1 shows an example of a system 100 that supports front-to-front bonding in a stacked memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), a bitcoin mining device, a blockchain mining device, or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked die architecture in which multiple semiconductor dies are physically and communicatively coupled. In some such implementations, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

To manufacture the system 100, it may be desirable to bond the memory die that includes the memory system 110 with the logic die that includes the host system 105 using a high-temperature bonding technique (e.g., a hybrid bonding technique, such as a copper-to-cooper (Cu2Cu) hybrid bonding technique at a temperature exceeding 300° C.). However, use of a high-temperature bonding technique may negatively impact temperature-sensitive materials that are A) used at later stages of the manufacture process, such as a temporary bonding material, B) added to the stacked memory system during later stages of the manufacturing process, such as conductive materials for conductive bumps, or both. A temperature-sensitive material may be a material that degrades or whose integrity is compromised upon application of a high temperature (e.g., a temperature exceeding 300° C.) or upon application of a temperature used for bonding the memory die with the logic wafer. Temperature-sensitive materials may also be referred to as temperature-susceptive materials or as materials with low thermal budgets, among other suitable terminology.

According to the techniques described herein, a memory die and logic wafer may be bonded together in a manner that permits use of a high-temperature bonding technique without negatively impacting temperature-sensitive materials. For example, the memory die and the logic wafer may be bonded together using a front-to-front (F2F, also referred to as face-to-face) bonding technique in which the front of the memory die is bonded with the front of the logic wafer. Use of F2F bonding, instead of alternative types of bonding such as front-to-back (F2B) bonding, may allow the bonding to occur before temperature-sensitive materials are implicated in the manufacturing process. In some examples, F2F bonding may be performed using the logic wafer as a base per se (e.g., rather than using as the base the logic wafer attached to a temporary carrier via a temporary bonding material). Thus, the stacked memory system may benefit from the advantages of using a high-temperature bonding technique without negatively impacting temperature-sensitive materials.

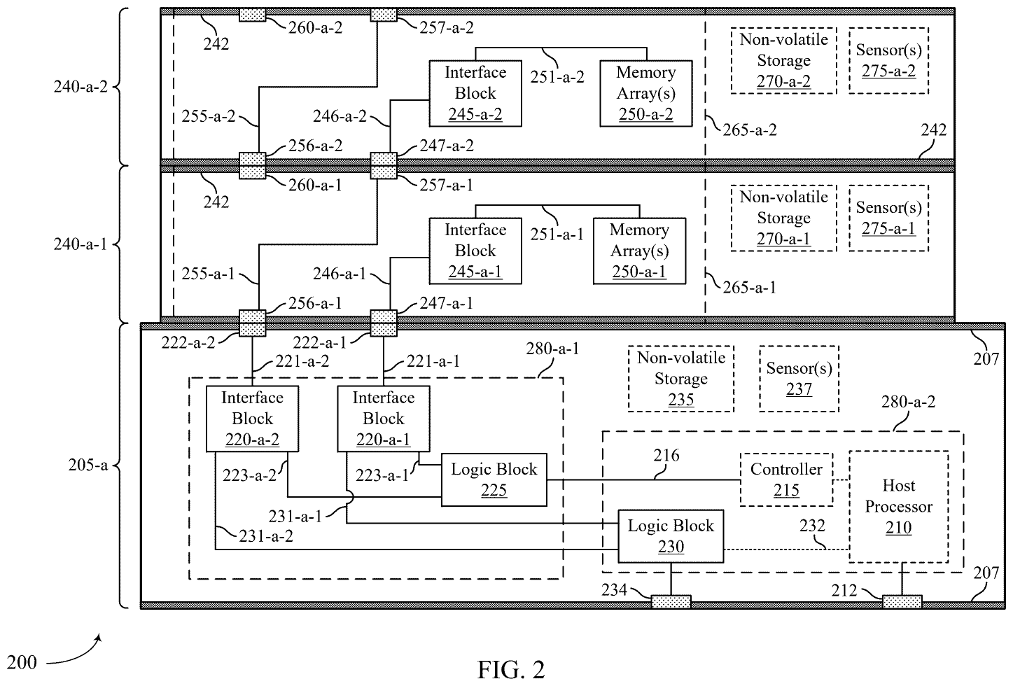

FIG. 2 shows an example of a system 200 (e.g., a semiconductor system, a system of coupled semiconductor dies, an HBM system, a 3D stacked memory system) that supports front-to-front bonding in a stacked memory system in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory system implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250. For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

Each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory array's 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

According to the techniques described herein, a memory die and logic wafer may be bonded together in a manner that permits use of a high-temperature bonding technique without negatively impacting temperature-sensitive materials. For example, the front of die 240-a-1 may be bonded with the front of die 205-a (or the wafer from which die 205-a is singulated) using F2F bonding. Use of F2F bonding, instead of alternative types of bonding such as F2B bonding, may allow the bonding to occur before temperature-sensitive materials are implicated in the manufacturing process. Thus, the stacked memory system may benefit from the advantages of using a high-temperature bonding technique without negatively impacting temperature-sensitive materials. In some examples, front of die 240-a-2 may be bonded with the back of die 240-a-1 using F2B bonding that occurs before die 240-a-1 is bonded with die 205-a (or the wafer from which die 205-a is singulated). The process of bonding multiple stacked memory dies with a logic die may be referred to as stack-to-die (S2D) bonding, and process of bonding multiple stacked memory dies with a logic wafer may be referred to as stack-to-wafer (S2 W) bonding.

Although referred to with reference to F2F die-to-wafer bonding, in which the front side of the memory die is bonded with the front side of the logic wafer, the techniques described herein may be used for die-to-die bonding, wafer-to-wafer bonding, and wafer-to-die bonding. However, F2F die-to-wafer bonding may have various advantages (e.g., fewer manufacturing steps, simpler manufacturing steps) relative to other techniques. Die-to-wafer bonding may also be referred to as chip-to-wafer (C2 W) bonding or other suitable terminology. Die-to-wafer bonding may be associated with higher yield relative to other techniques, such as die-to-die bonding, because unlike the other techniques it may permit bonding between dies that are known to be non-defective.

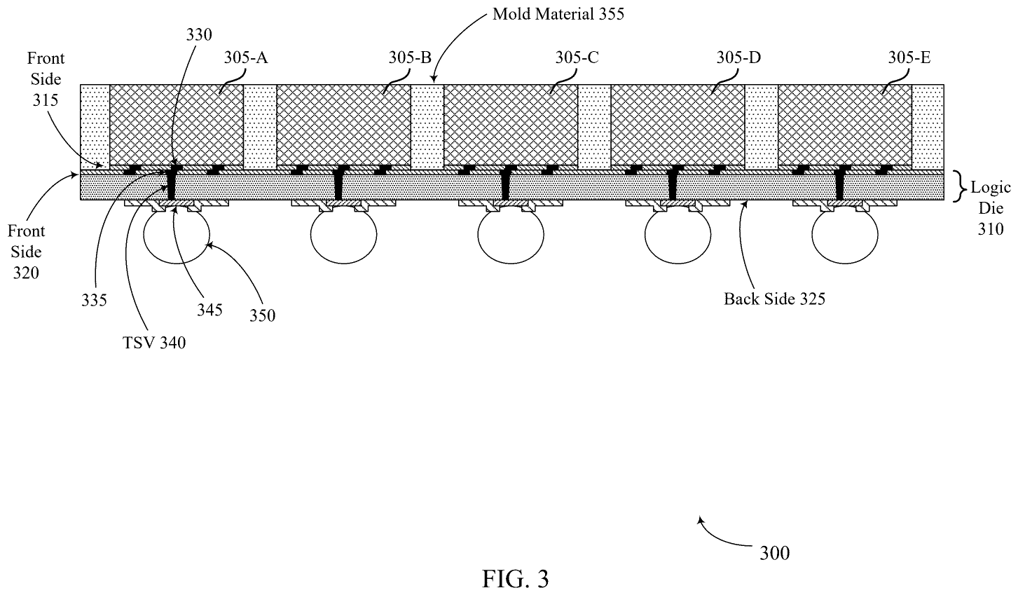

FIG. 3 shows a block diagram of a stacked memory system 300 that supports front-to-front bonding in accordance with examples as disclosed herein. The stacked memory system 300 may include single-stack memory dies 305 (e.g., memory die 305-a, memory die 305-b, memory die 305-c, memory die 305-d, memory die 305-e) and a logic die 310. In some implementations, there may be at least 2, 4, 6, or 8 single-stack memory dies 305. In some implementations, these dies 305 are top memory dies (dies that do not include through silicon vias (TSVs) and have thicker substrates for mechanical support and heat dissipation). In some examples, a mold material 355 (e.g., a dielectric material) may be disposed between the memory dies 305. The memory dies 305 may be examples of memory dies that include aspects of a memory system 110, may be examples of dies 240, or both. The logic die 310 may be an example of a logic die that includes aspects of the host system 105, may be examples of the die 205, or both. According to the techniques described herein, the front sides of the memory dies 305 may be bonded with the front side of the logic die 310.

Each memory die 305 may have a front side 315, where the front side of a memory die may refer to the side (e.g., surface) of the memory die that is doped during manufacturing to form various components such as transistors, where the memory cell are formed and may be the side from which BEOL circuitry is formed. Each memory die 305 may also have a back side that is opposite of the front side 315 of the memory die 305. In some examples, the memory dies 305 are volatile memory dies (e.g., DRAM dies) that include one or more volatile memory arrays (e.g., DRAM arrays). For a DRAM die, the front side of a memory die refers to where the transistor and capacitors are formed. The logic die 310 may have a front side 320, where the front side of a logic die may refer to the side (e.g., surface) of the logic die that is doped during manufacturing to form various components such as transistors and may be the side from which BEOL circuitry is formed. The logic die 310 may also have a back side 325 that is opposite the front side 320 of the logic die 310.

A memory die 305 may include one or more die-interface bond pads 330 (e.g., at the front side 315) that are bonded (e.g., after F2F bonding) with one or more corresponding die-interface bond pads 335 of the logic die 310. The logic die 310 may include one or more through-silicon-vias (TSVs) 340 that extend at least partially through the substrate (e.g., silicon) of the logic die 310. A TSV 340 may couple a die-interface bond pad 335 with an under-bump metallization (UBM) pad 345, which may be coupled (e.g., physically, electrically) with a conductive bump 350. Accordingly, the UBM pad 345, the TSV 340, the die-interface bond pad 335, and the die-interface bond pad 330 may form at least part of a conductive path between the conductive bump 350 and the memory die 305-a. A conductive path may refer to a path of materials, components, or both, that supports the flow of electrical signals (e.g., current, voltage).

So, due to F2F bonding, the conductive bumps 350 may be disposed on or otherwise coupled with the back side 325 of the logic die 310 (as opposed to being disposed on the front side 320 of the logic die 310, which may occur in other types of bonding). In some implementations, the conductive bumps 350 include materials having low melting temperatures (e.g., melting temperatures of approximately 270° C.).

A first component may be referred to as being physically coupled with a second component if the first component is in contact with the second component. A first component may be referred to as being electrically coupled with a second component if electrical signals are capable of being transferred between the first component and the second component. The term “coupled with” may refer to the state of being physically coupled, electrically coupled, or both. A first component may be referred to as being bonded with a second component if a bonding process (e.g., a hybrid bonding process) has been used to couple the first component with the second component.

In some implementations, FIG. 1 is similarly applicable for other types of memory devices, such as 3D NAND, where the face surface of the NAND cell array die is stacked and bonded to the face surface of the CMOS die. At stacking, the CMOS die may be in a non-singulated form as a CMOS wafer, and the NAND cell array die may be placed on top of the wafer in an F2F configuration.

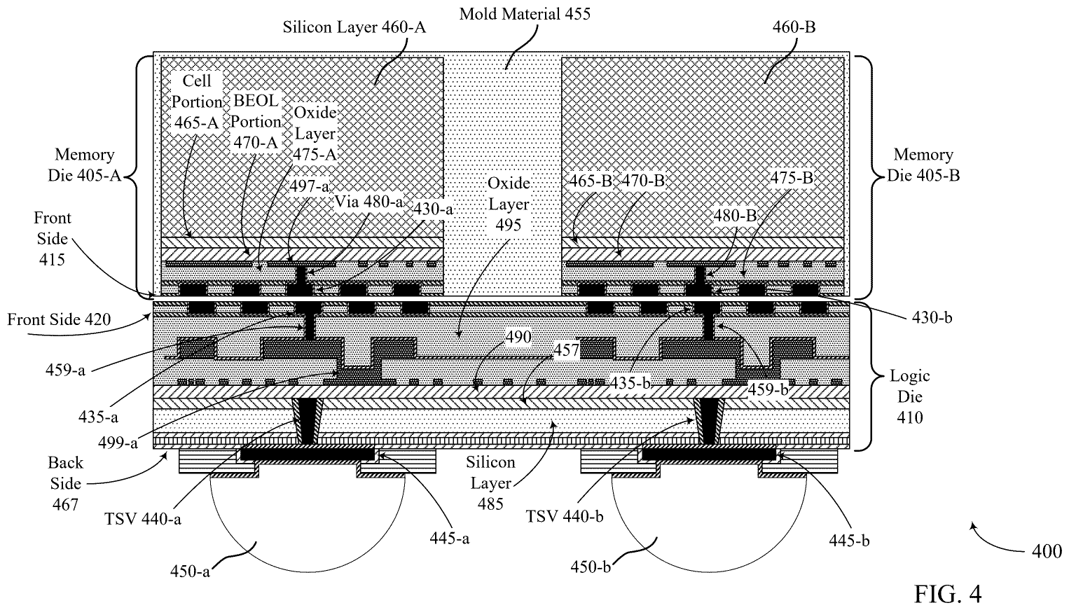

FIG. 4 shows a cross-section view of a stacked memory system 400 that supports front-to-front bonding in accordance with examples as disclosed herein. The stacked memory system 400 may be an example of the stacked memory system 300 as described with reference to FIG. 3. The stacked memory system 400 may include memory dies 405 (e.g., memory die 405-a, memory die 405-b) and a logic die 410. In some examples, a mold material 455 (e.g., a dielectric material) may be disposed between the memory dies 405. The cross-section view of the stacked memory system 400 may illustrate the arrangement of components of the memory dies 405 and the logic die 410 after the front sides of the memory dies 405 have been bonded with the front side of the logic die 410.

The memory die 405-a may have a front side 415-a, which may be separated from a silicon layer 460-a of the memory die 405-a by a BEOL portion 470-a of the memory die 405-a. The memory die 405-a may also have a back side that is opposite of the front side of the memory die 405-a. A BEOL portion, also referred to as BEOL circuitry, may refer to refer to a collection of interconnects (e.g., contacts, metal levels, bonding sites) formed within the oxide layer 475-a. The BEOL portion 470-a of the memory die 405-a may be separated from the silicon layer 460-a by a cell portion 465-a, which may also be referred to as a CMOS/cell portion, which includes an array of transistors and memory cells.

The logic die may have front side 420, which may be separated from a silicon layer 485 of the logic die 410 by a BEOL portion 490 of the logic die 410. The logic die 410 may also have a back side 467 that is opposite of the front side of the logic die 410. The BEOL portion 490, also referred to as BEOL circuitry, may refer to refer to a collection of interconnects (e.g., contacts, metal levels, bonding sites) formed within the oxide layer 495. The BEOL portion 490 of the logic die 410 may be separated from the silicon layer 485 by a cell portion 457, which may also be referred to as a CMOS/cell portion, which includes an array of transistors and memory cells.

A via 480-a may couple the BEOL portion 470-a with a die-interface bond pad 430-a of the memory die 405-a, which in turn may be coupled with a die-interface bond pad 435-a of the logic die 410. Although shown separated by white space the die-interface bond pads on the front side 415 of the memory dies 405-a may be in contact with the die-interface bond pads on the front side 420 of the logic die 410. A via 459-a may couple the die-interface bond pad 435-a of the logic die 410 with a TSV 440-a that extends at least partially through the logic die 410. In some implementations, the TSV 440-a is formed using via-middle (VM) process. In some other implementations, the TSV 440-a is formed using via-last (VL) process. A UBM pad 445-a may couple the TSV 440-a with a conductive bump 450-a of the logic die 410. In some implementations, the TSVs 440 are directly coupled with the conductive bumps 450. Thus, the UBM pad 445-a, the TSV 440-a, the via 459-a, the die-interface bond pad 435-a, the die-interface bond pad 430-a, and the via 480-a may form at least part of a conductive path between the conductive bump 450-a, the logic die 410, and the memory die 405-a.

A TSV (e.g., a VM TSV, a VL TSV) may have a large radius from the surface where it starts etching. In the stacked memory system 400, the smaller radius side of the TSVs (e.g., TSVs 440) may be towards the conductive bumps 450 (which may be different relative to other manufacturing techniques, in which the larger radius side may be toward the conductive bumps 450). For example, the radius of the end of the TSV 440-a that is closest to the conductive bump 450-a may be smaller than the radius of the end of the TSV 440-a that is farthest from the conductive bump 450-a.

The memory die 405-a may include an aluminum pad 497-a (e.g., a probe pad) that is coupled with die-interface bond pad 430-a. The die-interface bond pad 430-a may be bonded (e.g., hybrid bonded) with the die-interface bond pad 435-a. The die-interface bond pad 435-a may be coupled with the aluminum pad 499-a (e.g., a probe pad) of the logic die 410. This connection between aluminum pads and die-interface bonds across dies may be different relative to designs that are manufactured using other bonding techniques.

In some examples, a die-interface pad (e.g., a copper die-interface pad) may be formed on top of the BEOL portion 490 of the logic die 410.

The memory die 405-b may be configured similarly to the memory die 405-a and may include a silicon layer 460-b, a cell portion 465-b, an oxide layer 475-b, a via 480-b, and a die-interface bond pad 430-b. Similar to the memory die 405-a, the component of the memory die 405-b may be coupled with the die-interface bond pad 435-b, the via 459-b, the TSV 440-b, the UBM pad 445-b, and the conductive bump 450-b.

Thus, the memory dies 405 may be bonded with the logic die 410 in a F2F manner.

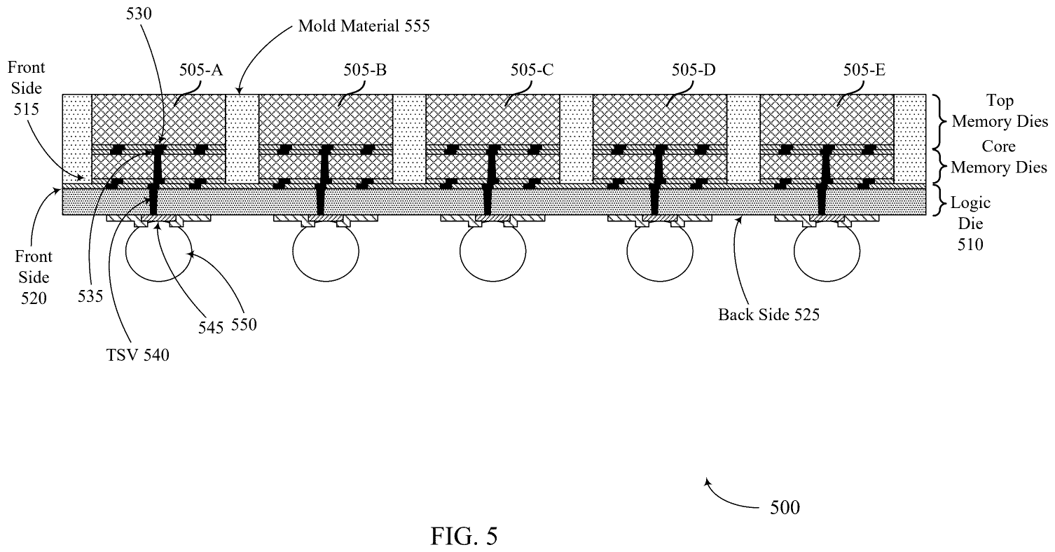

FIG. 5 shows a block diagram of a stacked memory system 500 that supports front-to-front bonding in accordance with examples as disclosed herein. The stacked memory system 500 may include double-stack memory dies 505 (e.g., memory die 505-a, memory die 505-b, memory die 505-c, memory die 505-d, and memory die 505-e) and a logic die 510. In some implementations, each stack of memory dies 505, which may include at least 4, 8, 12, or 16 dies. In some examples, a mold material 555 (e.g., a dielectric material) may be disposed between the memory dies 505. The memory dies 505 may be examples of memory dies that include aspects of a memory system 110, may be examples of dies 240, or both. The logic die 510 may be an example of a logic die that includes aspects of the host system 105, may be examples of the die 205, or both. According to the techniques described herein, the front sides of the memory dies 505 may be bonded with the front side of the logic die 510.

Each memory die 505 may have a front side 515, where the front side of a memory die may refer to the side (e.g., surface) of the memory die that is doped during manufacturing to form various components such as transistors and may be the side from which BEOL circuitry is formed. Each memory die 505 may also have a back side that is opposite of the front side 515 of the memory die 505. The front sides of the top memory dies may be bonded to the back sides of the core memory dies. In some implementations, the bonding between memory dies is by way of chip-to-wafer bonding or wafer-to-wafer bonding. In some examples, the memory dies 505 are volatile memory dies (e.g., DRAM dies) that include one or more volatile memory arrays (e.g., DRAM arrays). The logic die 510 may have a front side 520, where the front side of a logic die may refer to the side (e.g., surface) of the logic die that is doped during manufacturing to form various components such as transistors and may be the side from which BEOL circuitry is formed. The logic die 510 may also have a back side 525 that is opposite the front side 520 of the logic die 510.

A memory die 505 may include one or more die-interface bond pads 530 (e.g., at the front side 515) that are bonded (e.g., after F2F bonding) with one or more corresponding die-interface bond pads 535 of the logic die 510. The logic die 510 may include one or more TSVs 540 that extend at least partially through the substrate (e.g., silicon) of the logic die 510. A TSV 540 may couple a die-interface bond pad 535 with a UBM pad 545, which may be coupled (e.g., physically, electrically) with a conductive bump 550. Accordingly, the UBM pad 545, the TSV 540, the die-interface bond pad 535, and the die-interface bond pad 530 may form at least part of a conductive path between the conductive bump 550 and the memory die 505-a.

So, due to F2F bonding, the conductive bumps 550 may be disposed on or otherwise coupled with the back side 525 of the logic die 510 (as opposed to being disposed on the front side 520 of the logic die 510, which may occur in other types of bonding).

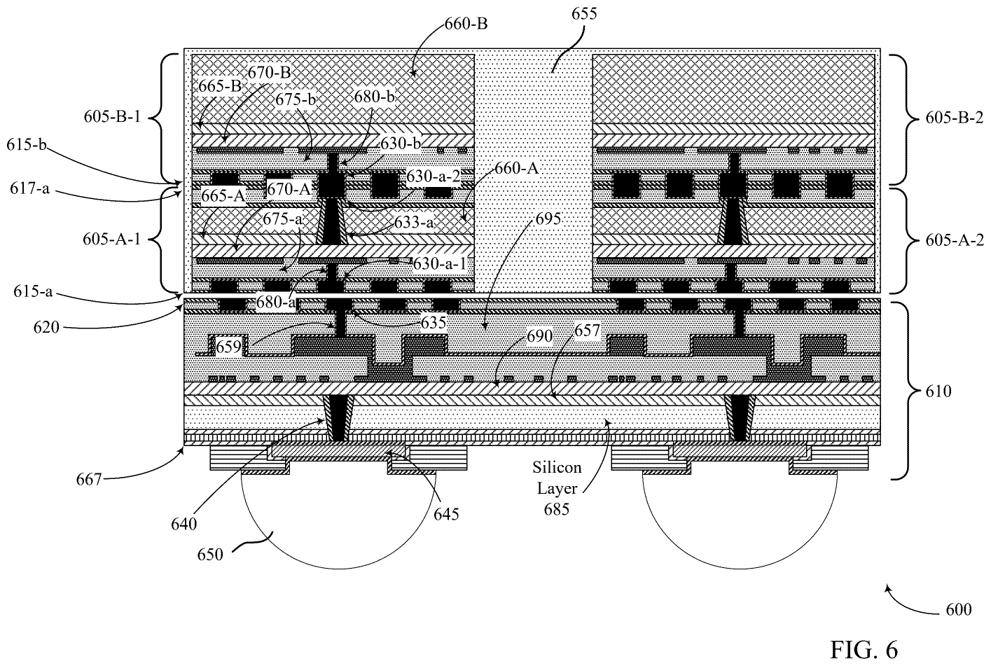

FIG. 6 shows a cross-section view of a stacked memory system 600 that supports front-to-front bonding in accordance with examples as disclosed herein. The stacked memory system 600 may be an example of the stacked memory system 500 as described with reference to FIG. 5. The stacked memory system 600 may include memory dies 605 (e.g., memory die 605-a-1, memory die 605-a-2, memory die 605-b-1, memory die 605-b-2) and a logic die 610. In some examples, a mold material 655 (e.g., a dielectric material) may be disposed between the memory dies 605. The cross-section view of the stacked memory system 600 may illustrate the arrangement of components of the memory dies 605 and the logic die 610 after A) the front sides of the memory dies 605-b have been bonded with the back sides of the memory dies 606-a, and B) the front sides of the memory dies 605-a have been bonded with the front side of the logic die 610.

The front side of a die may refer to a surface of the die or may refer to a section of the die that includes certain components. For example, referring to the memory die 605-b-1, the front side of the memory die may include front end of line (FEOL) complementary metal-oxide semiconductor (CMOS) transistors, middle of line (MOL) cell array (e.g., cell portion 665), and BEOL interconnects (e.g., die-interface bond pads, vias), whereas the back side may include silicon exclusive of these components. Referring to the memory die 605-a-1, the front side of the memory die may include FEOL CMOS transistors, MOL Cell Array (e.g., cell portion 665-a) and associated interconnects, and BEOL interconnects (e.g., TSVs, die-interface bond pads, vias), whereas the back side may include interconnects (e.g., hybrid bonding pads, TSVs) exclusive of these components. Referring to the logic die 610, the front side of the logic die may include FEOL CMOS transistors, MOL interconnects, BEOL interconnects (TSVs, die-interface bond pads, vias), whereas the back side may include an RDL portion and conductive bump(s) (e.g., C4 solder bumps).

The arrangement of memory die 605-a-2 may be similar to the arrangement of memory die 605-a-1, and thus corresponding reference signs and description are omitted for clarity and brevity. The arrangement of memory die 605-b-2 may be similar to the arrangement of memory die 605-b-1, and thus corresponding reference signs and description are omitted for clarity and brevity.

According to the techniques described herein, the front side 615-b of the memory die 605-b-1 may be bonded with the back side 617-a of the memory die 605-a-1. And the front side 615-a of the memory die 605-a-1 may be bonded with the front side 620 of the logic die 610. Because the memory die 605-a-1 is bonded with the memory die 605-b (e.g., instead of being a stand-alone memory die), the memory die 605-a-1 may have one or more TSVs that couple the logic die 610 with the memory die 605-b-1.

The front side 615-b of the memory die 605-b may be separated from a silicon layer 660-b of the memory die 605-a by a BEOL portion 670-b of the memory die 605-b-1. The back side of the memory die 605-b may be opposite of the front side 615-b of the memory die 605-b-1. A BEOL portion, also referred to as BEOL circuitry, may refer to a collection of interconnects (e.g., contacts, metal levels, bonding sites) formed within the oxide layer 675-b. The BEOL portion 670-b of the memory die 605-b-1 may be separated from the silicon layer 660-b by a cell portion 665-b, which may also be referred to as a CMOS/cell portion, which includes an array of transistors and memory cells.

A via 680-b may couple the BEOL portion 670-b with a die-interface bond pad 630-b of the memory die 605-b-1, which in turn may be coupled with a die-interface bond pad 635-a-2 of the logic die 605-a-1. The die-interface bond pad 630-a-2 may be coupled with a TSV 633-a that extends at least partially through the silicon layer 660-a and that is coupled with the BEOL portion 670-a. Thus, the TSV 633-a may couple the memory die 605-a-1 with the memory die 605-b-1.

The front side 615-a of the memory die 605-a may be separated from a silicon layer 660-a of the memory die 605-a by a BEOL portion 670-a of the memory die 605-a. The back side 617-a of the memory die 605-a may be opposite of the front side of the memory die 605-a. A BEOL portion, also referred to as BEOL circuitry, may refer to a collection of interconnects (e.g., contacts, metal levels, bonding sites) formed within the oxide layer 675-a. The BEOL portion 670-a of the memory die 605-a may be separated from the silicon layer 660-a by a cell portion 665-a, which may also be referred to as a CMOS/cell portion, which includes an array of transistors and memory cells.

The logic die may have front side 620, which may be separated from a silicon layer 685 of the logic die 610 by a BEOL portion 690 of the logic die 610. The logic die 610 may also have a back side 667 that is opposite of the front side of the logic die 610. The BEOL portion 690, also referred to as BEOL circuitry, may refer to a collection of interconnects (e.g., contacts, metal levels, bonding sites) formed within the oxide layer 695. The BEOL portion 690 of the logic die 610 may be separated from the silicon layer 685 by a cell portion 657, which may also be referred to as a CMOS/cell portion, which includes an array of transistors and memory cells.

A via 480-a may couple the BEOL portion 670-a with a die-interface bond pad 630-a-1 of the memory die 605-a-1, which in turn may be coupled with a die-interface bond pad 635 of the logic die 610. A via 659 may couple the die-interface bond pad 635 of the logic die 610 with a TSV 640 that extends at least partially through the logic die 610. A UBM pad 645 may couple the TSV 640 with a conductive bump 650 of the logic die 610. Thus, the UBM pad 645, the TSV 640, the via 659, the die-interface bond pad 635, the die-interface bond pad 630-a-a, and the via 680-a may form at least part of a conductive path between the conductive bump 650, the logic die 610, and the memory die 605-a-1.

Thus, the memory dies 605-a and 605-b may be bonded together in a B2F manner and the memory dies 605-a may be bonded with the logic die 610 in a F2F manner.

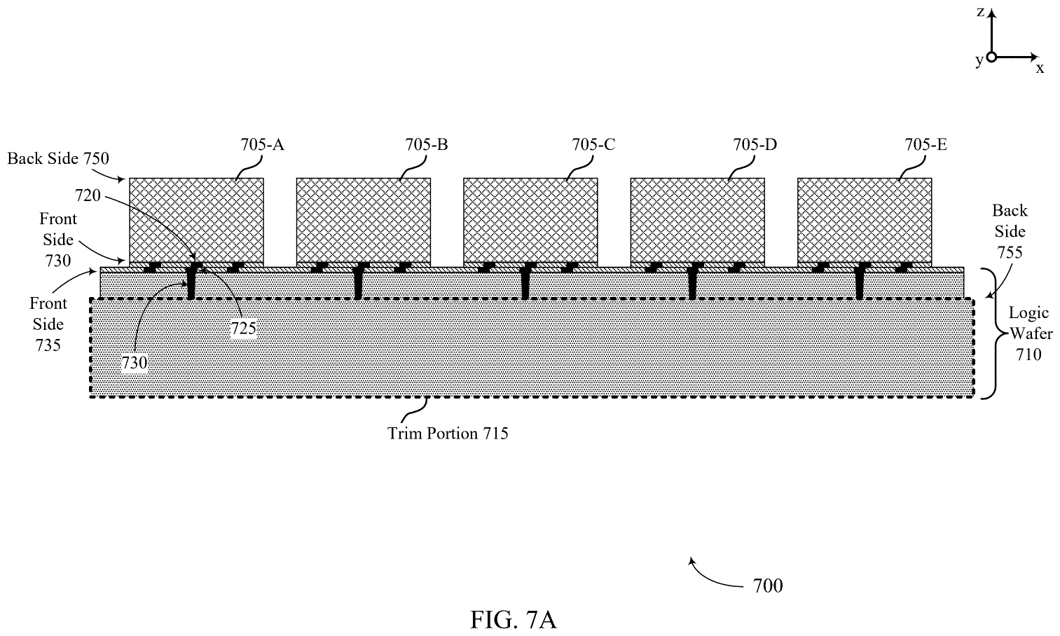

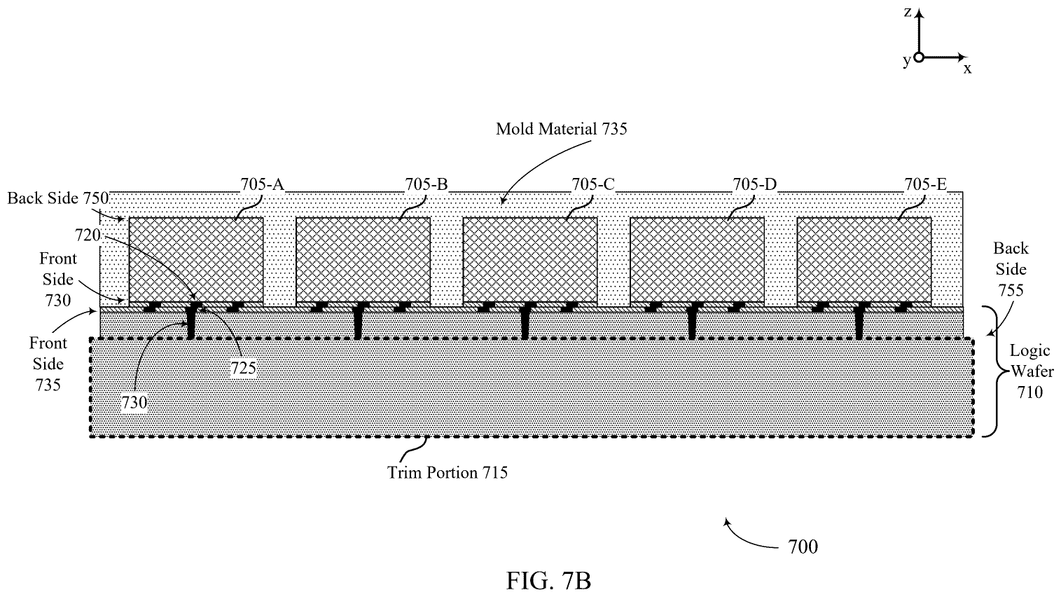

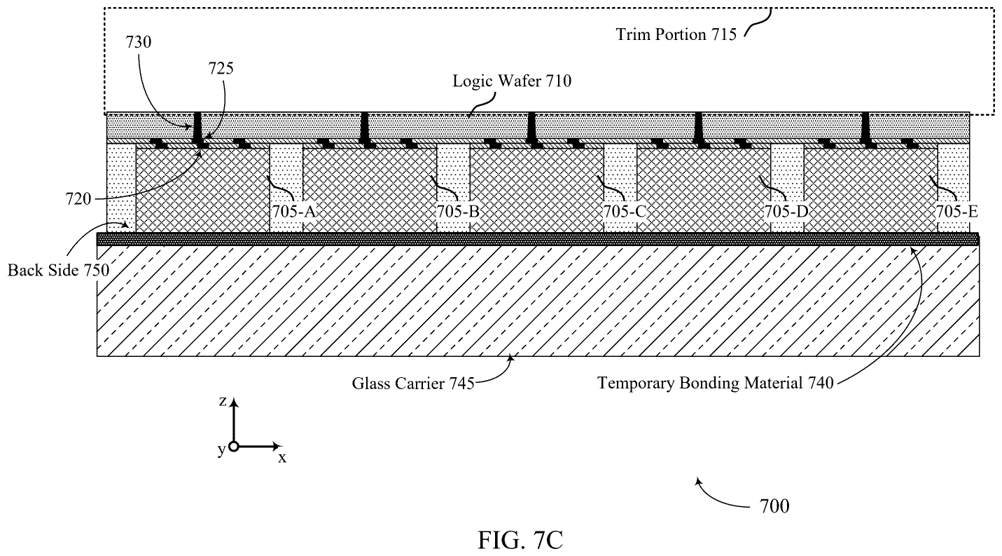

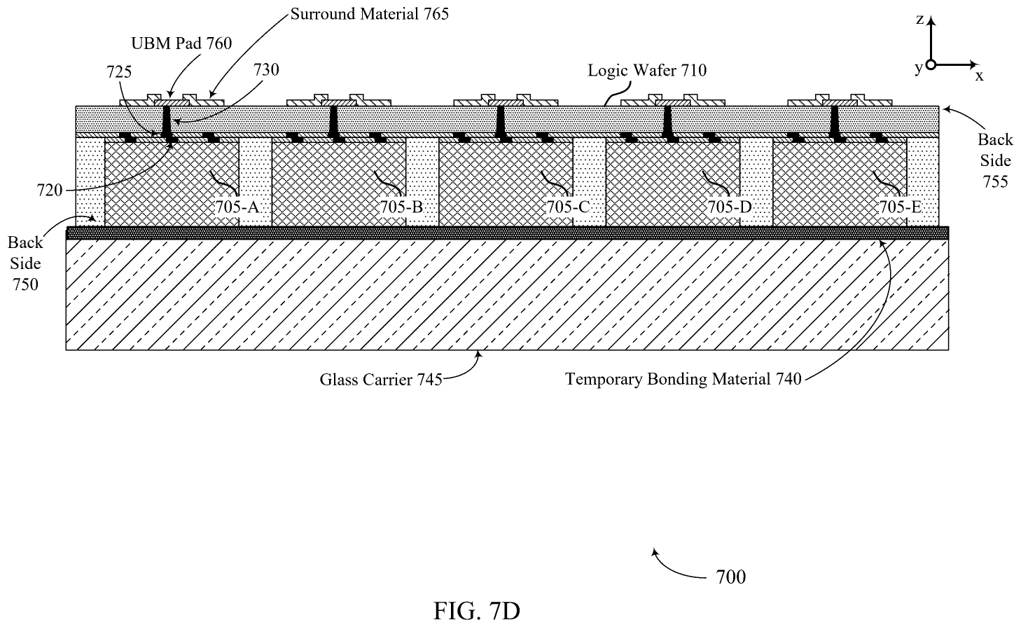

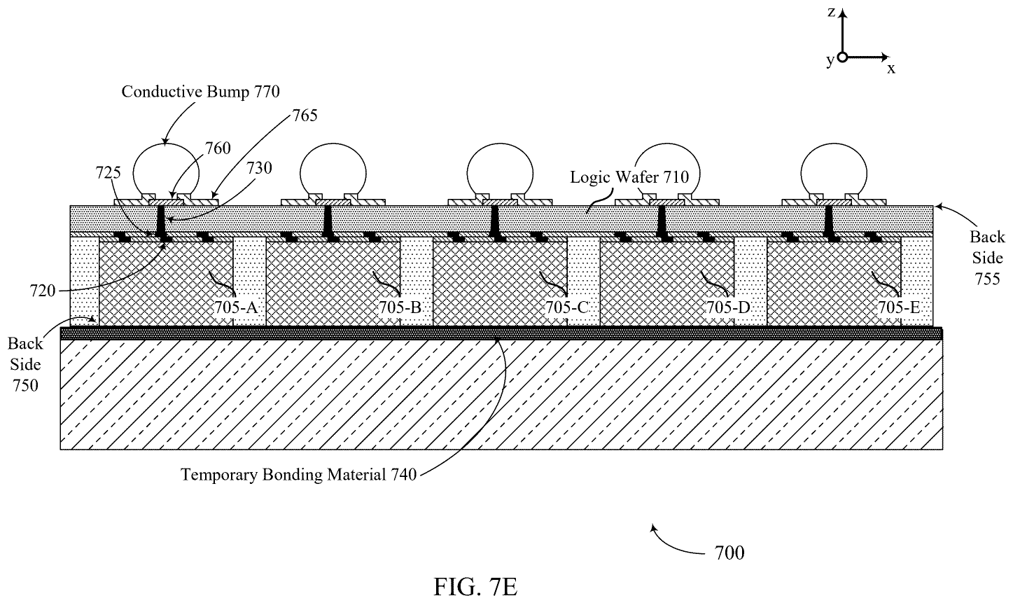

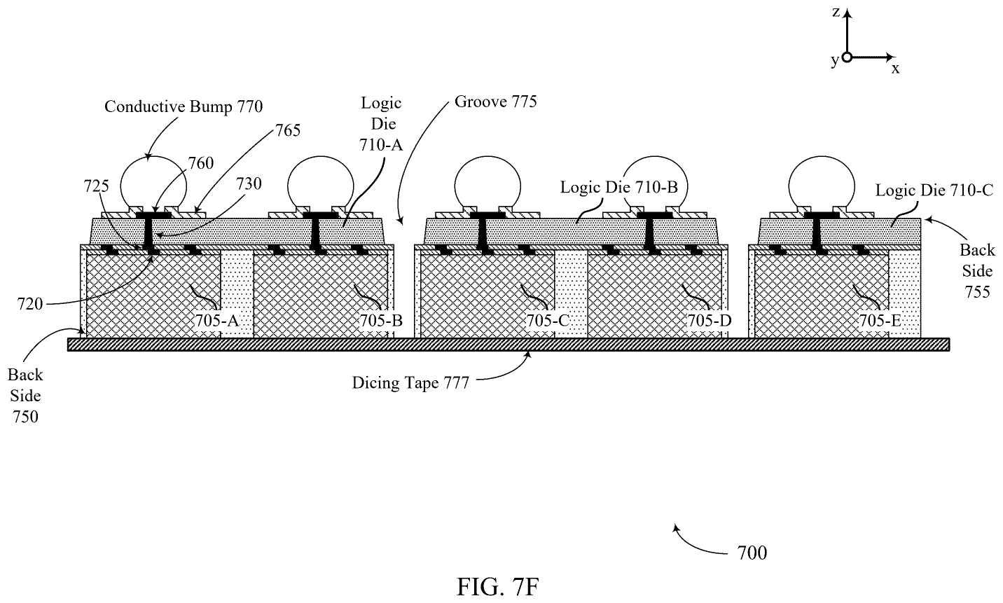

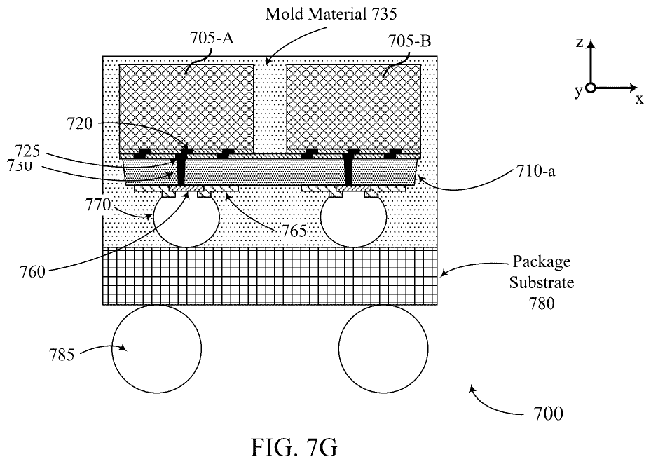

FIGS. 7A through 7G illustrate various steps of a manufacturing process, for a stacked memory system with single-stacked memory dies, which uses a high-temperature bonding technique to bond one or more memory dies with a logic wafer in an F2F manner. Unlike in other bonding techniques, the F2F bonding of the memory dies with the logic wafer may occur before other steps that involve temperature-sensitive materials. For example, F2F bonding may occur before application of a temperature-sensitive temporary bonding material that is used to flip the stacked memory system for additional processing. As another example, F2F bonding may occur before deposition of a temperature-sensitive conductive material that forms conductive bumps. Additionally, the conductive bumps coupled with the logic wafer may be coupled with the back side of the logic wafer instead of the front side of the logic wafer. Furthermore, the F2F bonding of the memory dies with the logic wafer may not need an additional base or sacrificial wafer.

FIG. 7A shows a cross-section view of a stacked memory system 700 at a stage A of a manufacturing process that supports front-to-front bonding in accordance with examples as disclosed herein. The stacked memory system 700 may be an example of the stacked memory system 300 or the stacked memory system 400 as described with reference to FIGS. 3 and 4, respectively. The stacked memory system 700 may be described in the context of the 3D-coordinate system as illustrated. The stacked memory system 700 may include memory dies 705 (e.g., memory die 705-a, memory die 705-b, memory die 705-c, memory die 705-d, and memory die 705-e) and a logic wafer 710. As part of the manufacturing process, the front sides of the memory dies 705 may be bonded with the front side of the logic wafer 710 using a high-temperature bonding technique (e.g., hybrid bonding of temperature greater than 300° C.).

A memory die 705 may include a back side 750 and one or more die-interface bond pads 720. The logic wafer 710 may include a back side 755 and one or more die-interface bond pads 725. Bonding a memory die 705 with the logic wafer 710 may include bonding the die-interface bond pads 720 with the die-interface bond pads 725. The logic wafer 710 may include one or more TSVs 730 that are coupled with the die-interface bond pads 725. The logic wafer 710 may include a substrate with a trim portion 715 that is removed at a later stage of the manufacturing process.

In some implementations, a wafer having memory dies 705 is bonded to logic wafer 710. In some implementations, the wafer has memory dies 705, which may be the product of the manufacturing memory dies 705. Alternatively, the wafer having memory dies 705, which may be a product of selecting know-good-die (KGD) memory dies 705 and then reconstructing a wafer with KGD memory dies.

FIG. 7B shows a cross-section view of a stacked memory system 700 at a stage B of a manufacturing process that supports front-to-front bonding in accordance with examples as disclosed herein. As part of the manufacturing process, a mold material 735 may be deposited over the memory dies 705. The mold material 735 may at least partially overlay, and may be partially between (e.g., may separate), the memory dies 705.

FIG. 7C shows a cross-section view of a stacked memory system 700 at a stage C of a manufacturing process that supports front-to-front bonding in accordance with examples as disclosed herein. As part of the manufacturing process, a temporary bonding material 740 (e.g., an adhesive material) may be deposited over (e.g., on) the back sides 750 of the memory dies 705. In some examples the temporary bonding material 740 may be in contact with the back sides 750 of the memory dies 705. The temporary bonding material 740 may allow the stacked memory system 700 to be coupled with a glass carrier 745, which may be comprised of a glass material, so that the stacked memory system 700 may be inverted (e.g., flipped upside down) for additional processing. Because deposition of the temporary bonding material 740 occurs after the F2F bonding between the memory dies 705 and the logic wafer 710, the temporary bonding material 740 may be unaffected by the high-temperature used for the F2F bonding, and thus may maintain greater integrity compared to other bonding techniques, such as F2B bonding.

After (or potentially before) coupling the stacked memory system 700 with the glass carrier 745, the trim portion 715 may be removed. Removing the trim portion 715 may expose the TSVs 730.

FIG. 7D shows a cross-section view of a stacked memory system 700 at a stage D of a manufacturing process that supports front-to-front bonding in accordance with examples as disclosed herein. As part of the manufacturing process, one or more UBM pads 760 may be added to the back side 755 of the logic wafer 710. For example, a UBM pad 760 may be added above the TSV 730 in the z-direction and in some examples may align with the TSV 730 in the y-direction, the x-direction, or both. The UBM pad 760 may be electrically coupled with the TSV 730 and in some examples may be physically coupled with (e.g., in contact with) the TSV 730. The UBM pad 760 and the TSV 730 may support the communication of electrical signals between the logic wafer 710 and the memory die 705-a.

In some examples, the UBM pads 760 may be at least partially surrounded by, and potentially coupled with, a surround material 765. The surround material 765 may be an inorganic dielectric material such as a polymide material. In some examples, the UBM pads 760 may be formed using a semi-additive physical vapor deposition (PVD) process and polymide passivation process.

FIG. 7E shows a cross-section view of a stacked memory system 700 at a stage E of a manufacturing process that supports front-to-front bonding in accordance with examples as disclosed herein. As part of the manufacturing process, one or more conductive bumps 770 (e.g., micro-bumps (μ-bumps)) may be formed along the back side 755 of the logic wafer 710. The conductive bumps 770 may be coupled with respective UBM pads 760. In some examples, the conductive bumps 770 may be formed using a C4 solder reflow process.

FIG. 7F shows a cross-section view of a stacked memory system 700 at a stage F of a manufacturing process that supports front-to-front bonding in accordance with examples as disclosed herein. As part of the manufacturing process, one or more grooves 775 may be formed within the logic wafer 710 and the mold material 735. A groove 775 may be formed by removing a portion of the logic wafer 710, by removing a portion of the mold material 735, or both. In some examples, the grooves 775 may be formed using a laser grooving process, using a blade singulation process, or both. In some examples, the temporary bonding material 740 and the glass carrier 745 may be replaced with dicing tape 777 before formation of the grooves 775. After formation of the grooves 775, the different pieces of the logic wafer 710 may be referred to as logic die 710-a, logic die 710-b, and logic die 710-c. A groove may also be referred to as a void or other suitable terminology.

FIG. 7G shows a cross-section view of a stacked memory system 700 at a stage G of a manufacturing process that supports front-to-front bonding in accordance with examples as disclosed herein. The stacked memory system 700 may include logic die 710-a, which may be F2F bonded with memory die 705-a and memory die 705-b. Additional mold material 735 may be deposited to fill in the groove 775, to at least partially surround the conductive bumps 770, or both. The conductive bumps 770 may be coupled with a package substrate 780, which in turn may be coupled with conductive bumps 785, which may be examples of ball grid array (BGA) bumps.

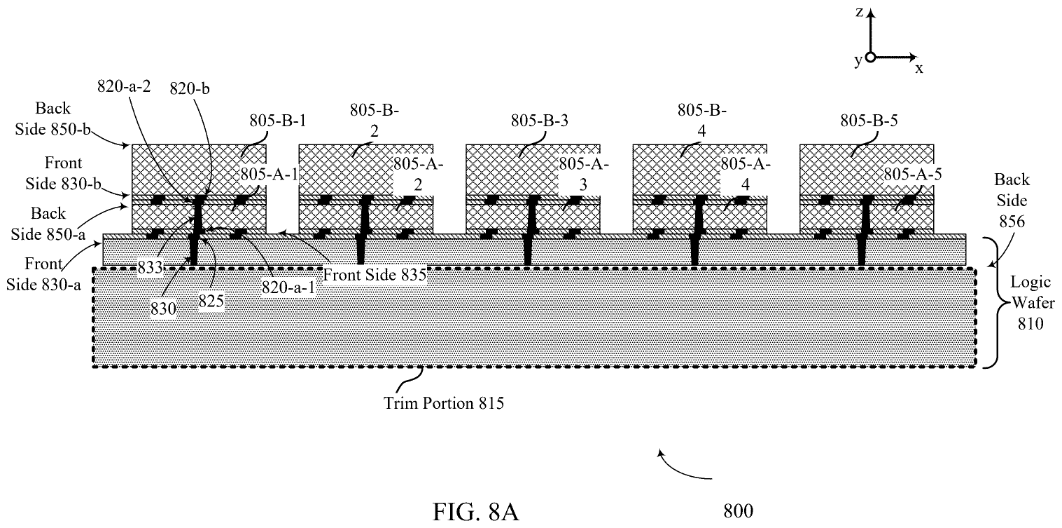

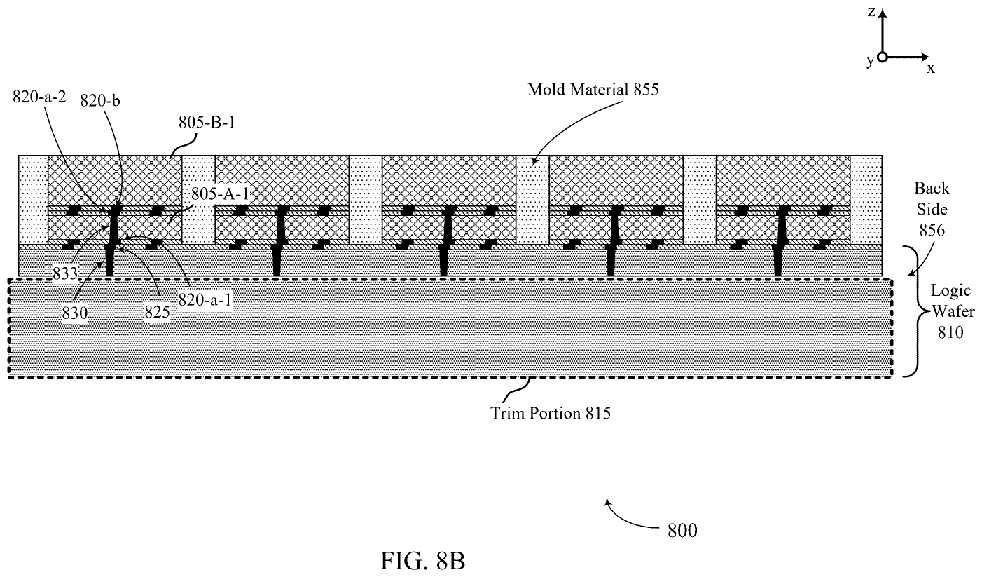

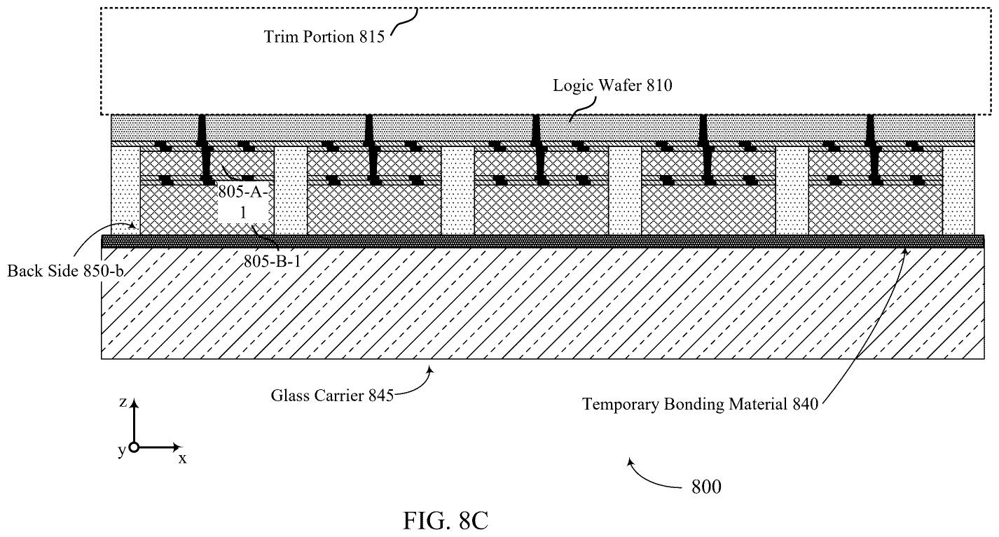

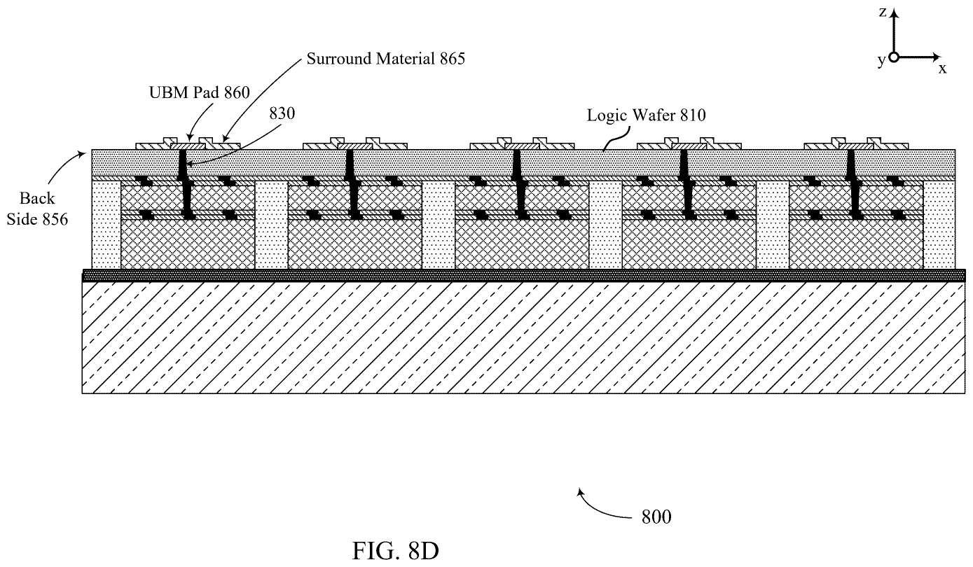

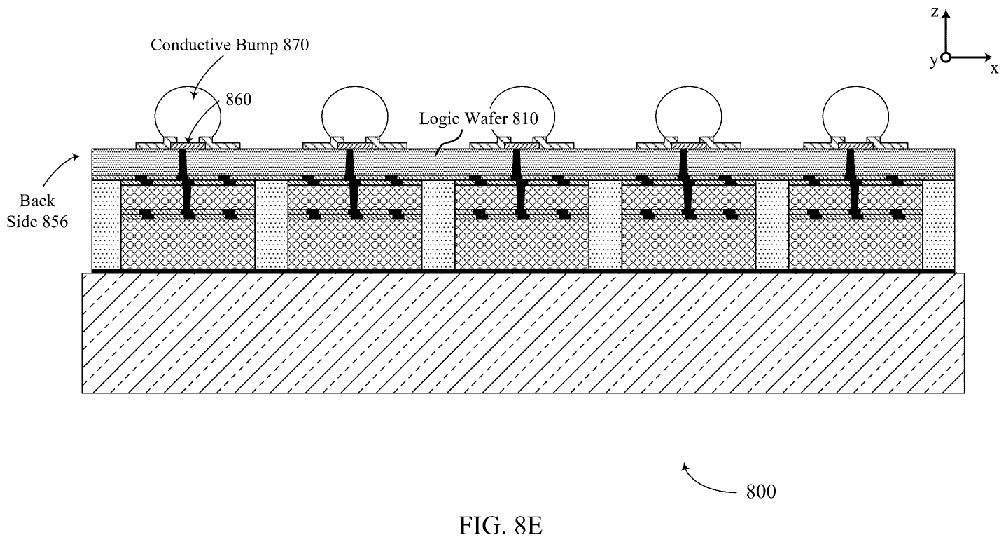

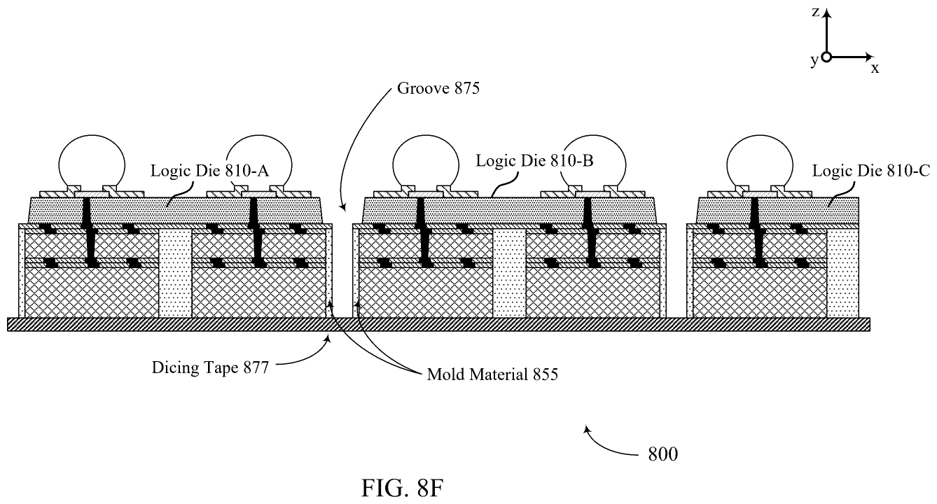

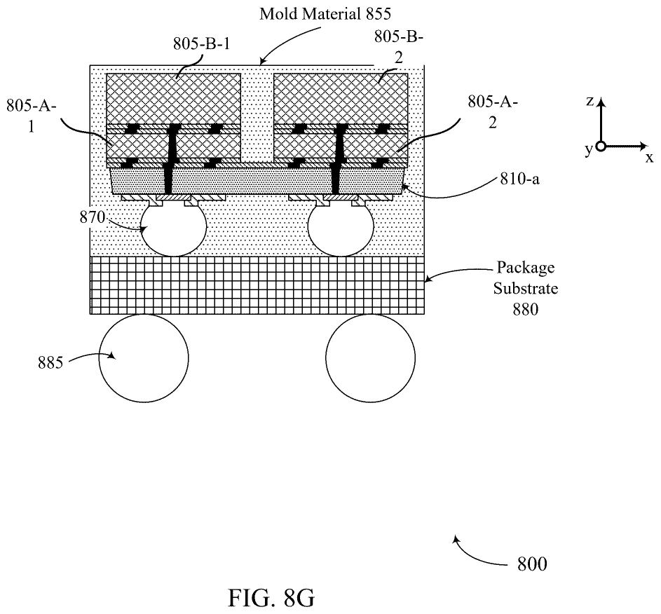

FIGS. 8A through 8G illustrate various steps of a manufacturing process, for a stacked memory system with at least two stacked memory dies, that bonds one or more memory dies with a logic wafer in an F2F manner. Unlike in other bonding techniques, the F2F bonding of the memory dies with the logic wafer may occur before other steps that involve temperature-sensitive materials. For example, F2F bonding may occur before application of a temperature-sensitive temporary bonding material that is used to flip the stacked memory system for additional processing. As another example, F2F bonding may occur before deposition of a temperature-sensitive conductive material that forms conductive bumps. Additionally, the conductive bumps coupled with the logic wafer may be coupled with the back side of the logic wafer instead of the front side of the logic wafer.

FIG. 8A shows a cross-section view of a stacked memory system 800 at a stage A of a manufacturing process that supports front-to-front bonding in accordance with examples as disclosed herein. The stacked memory system 800 may be an example of the stacked memory system 500 or the stacked memory system 600 as described with reference to FIGS. 5 and 6, respectively. The stacked memory system 800 may be described in the context of the 3D-coordinate system as illustrated. The stacked memory system 800 may include memory dies 805 (e.g., memory die 805-a-1 through memory die 805-a-5 and memory die 805-b-a through memory die 805-b-5) and a logic wafer 810.

As part of the manufacturing process, the front sides 830-b of the memory dies 805-b may be die-to-die bonded with the back sides 850-a of the memory dies 805-a. Further, the front sides 830-a of the memory dies 805-a may be die-to-wafer bonded with the front side 835 of the logic wafer 810 using a high-temperature bonding technique (e.g., hybrid bonding). The memory dies 805-a may be bonded with the memory dies 805-b before the memory dies 805-a are bonded with the logic wafer 810. In some examples, the memory dies 805-a may be referred to as core memory dies and the memory dies 805-b may be referred to as top memory dies.

A memory die 805-a may include one or more die-interface bond pads 820-a and a memory die 805-b may include one or more die-interface bond pads 820-b. Bonding a memory die 805-a with a memory die 805-b may include bonding the die-interface bond pads 820-a with the die-interface bond pads 820-b. A memory die 805-a may include one or more TSVs 833 that are coupled with the die-interface bond pad 820-a-1 as well coupled with the die-interface bond pad 820-a-2. Thus, the memory dies 805-b may be coupled with the logic wafer 810 through the TSVs 833.

The logic wafer 810 may include a back side 856 and one or more die-interface bond pads 825. Bonding a memory die 805-a with the logic wafer 810 may include bonding the die-interface bond pads 820-a with the die-interface bond pads 825. The logic wafer 810 may include one or more TSVs 830 that are coupled with the die-interface bond pads 825. The logic wafer 810 may include a substrate with a trim portion 815 that is removed at a later stage of the manufacturing process.

FIG. 8B shows a cross-section view of a stacked memory system 800 at a stage B of a manufacturing process that supports front-to-front bonding in accordance with examples as disclosed herein. As part of the manufacturing process, a mold material 855 may be deposited over the memory dies 805. The mold material 855 may at least partially overlay, and may be partially between (e.g., may separate), the memory dies 805.

FIG. 8C shows a cross-section view of a stacked memory system 800 at a stage C of a manufacturing process that supports front-to-front bonding in accordance with examples as disclosed herein. As part of the manufacturing process, a temporary bonding material 840 (e.g., an adhesive material) may be deposited over (e.g., on) the back sides 850-b of the memory dies 805-b. In some examples the temporary bonding material 840 may be in contact with the back sides 850-b of the memory dies 805. The temporary bonding material 840 may allow the stacked memory system 800 to be coupled with a glass carrier 845, which may be comprised of a glass material, so that the stacked memory system 800 may be inverted (e.g., flipped upside down) for additional processing. Because deposition of the temporary bonding material 840 occurs after the F2F bonding between the memory dies 805 and the logic wafer 810, the temporary bonding material 840 may be unaffected by the high-temperature used for the F2F bonding, and thus may maintain greater integrity compared to other bonding techniques, such as F2B bonding.

After (or potentially before) coupling the stacked memory system 800 with the glass carrier 845, the trim portion 815 may be removed. Removing the trim portion 815 may expose the TSVs 830.

FIG. 8D shows a cross-section view of a stacked memory system 800 at a stage D of a manufacturing process that supports front-to-front bonding in accordance with examples as disclosed herein. As part of the manufacturing process, one or more UBM pads 860 may be added to the back side 856 of the logic wafer 810. For example, a UBM pad 860 may be added above the TSV 830 in the z-direction and in some examples may align with the TSV 830 in the y-direction, the x-direction, or both. The UBM pad 860 may be electrically coupled with the TSV 830 and in some examples may be physically coupled with (e.g., in contact with) the TSV 830. The UBM pad 860 and the TSV 830 may support the communication of electrical signals between the logic wafer 810 and the memory die 805-a.

FIG. 8E shows a cross-section view of a stacked memory system 800 at a stage E of a manufacturing process that supports front-to-front bonding in accordance with examples as disclosed herein. As part of the manufacturing process, one or more conductive bumps 870 (e.g., μ-bumps) may be formed along the back side 856 of the logic wafer 810. The conductive bumps 870 may be coupled with respective UBM pads 860. In some examples, the conductive bumps 870 may be formed using a C4 solder reflow process.

In some examples, the UBM pads 860 may be at least partially surrounded by, and potentially coupled with, a surround material 865. The surround material 865 may be an inorganic dielectric material such as a polymide material. In some examples, the UBM pads 860 may be formed using a semi-additive PVD process and polymide passivation process.

FIG. 8F shows a cross-section view of a stacked memory system 800 at a stage F of a manufacturing process that supports front-to-front bonding in accordance with examples as disclosed herein. As part of the manufacturing process, one or more grooves 875 may be formed within the logic wafer 810 and the mold material 855. A groove 875 may be formed by removing a portion of the logic wafer 810, by removing a portion of the mold material 855, or both. In some examples, the grooves 875 may be formed using a laser grooving process, using a blade singulation process, or both. In some examples, the temporary bonding material 840) and the glass carrier 845 may be replaced with dicing tape 877 before formation of the grooves 875. After formation of the grooves 875, the different pieces of the logic wafer 810 may be referred to as logic die 810-a, logic die 810-b, and logic die 810-c. A groove may also be referred to as a void or other suitable terminology.

FIG. 8G shows a cross-section view of a stacked memory system 800 at a stage G of a manufacturing process that supports front-to-front bonding in accordance with examples as disclosed herein. The stacked memory system 800 may include logic die 810-a, which may be F2F bonded with memory die 805-a-1 and memory die 805-a-2. Memory die 805-b-1 may be F2B bonded with memory die 805-a-1 and memory die 805-b-2 may be F2B bonded with memory die 805-a-2. Additional mold material 855 may be deposited to fill in the groove 875, to at least partially surround the conductive bumps 870, or both. The conductive bumps 870 may be coupled with a package substrate 880, which in turn may be coupled with conductive bumps 885, which may be examples of BGA bumps.

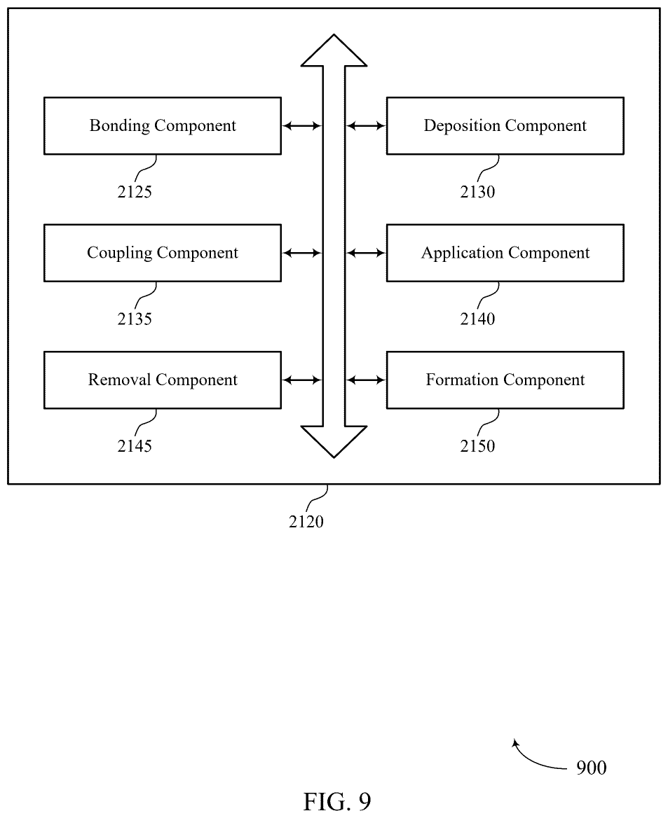

FIG. 9 shows a block diagram 900 of a manufacturing system 920 that supports front-to-front bonding in a stacked memory system in accordance with examples as disclosed herein. The manufacturing system 920 may be an example of aspects of a manufacturing system as described with reference to FIGS. 1 through 8. The manufacturing system 920, or various components thereof, may be an example of means for performing various aspects of front-to-front bonding in a stacked memory system as described herein. For example, the manufacturing system 920 may include a bonding component 925, a deposition component 930, a coupling component 935, an application component 940, a removal component 945, a formation component 950, or any combination thereof. Each of these components, or components of subcomponents thereof (e.g., one or more processors, one or more memories), may communicate, directly or indirectly, with one another (e.g., via one or more buses).

The bonding component 925 may be configured as or otherwise support a means for bonding a front side of a volatile memory die with a front side of a logic wafer, the front side of the logic wafer separated from a silicon layer of the logic wafer by at least a back-end-of-line (BEOL) portion of the logic wafer. The deposition component 930 may be configured as or otherwise support a means for forming a conductive bump on a back side of the logic wafer based at least in part on bonding the front side of the volatile memory die with the front side of the logic wafer, the back side of the logic wafer separated from the BEOL portion by at least the silicon layer. The coupling component 935 may be configured as or otherwise support a means for coupling the conductive bump on the back side of the logic wafer with a package substrate based at least in part on forming the conductive bump.

In some examples, the application component 940 may be configured as or otherwise support a means for applying a temporary bond material to a back side of the volatile memory die based at least in part on bonding the front side of the volatile memory die with the front side of the logic wafer. In some examples, the removal component 945 may be configured as or otherwise support a means for removing a trim portion of the logic wafer based at least in part on applying the temporary bond material, where removing the trim portion exposes a through-silicon-via (TSV) that extends through the silicon layer of the logic wafer.

In some examples, the formation component 950 may be configured as or otherwise support a means for forming an under-bump metallization (UBM) pad on the logic wafer based at least in part on removing the trim portion of the logic wafer, where the UBM pad is coupled with the conductive bump and the TSV.

In some examples, the deposition component 930 may be configured as or otherwise support a means for depositing a mold material over the volatile memory die, where the temporary bond material is applied based at least in part on depositing the mold material.

In some examples, the removal component 945 may be configured as or otherwise support a means for removing a trim portion of the mold material, where removing the trim portion exposes a back side of the volatile memory die, and where the temporary bond material is applied based at least in part on removing the trim portion of the mold material.

In some examples, the bonding component 925 may be configured as or otherwise support a means for bonding a back side of the volatile memory die with a front side of a second volatile memory die, where the front side of the volatile memory die is bonded with the front side of the logic wafer after bonding the back side of the volatile memory die with the front side of the second volatile memory die.

In some examples, the application component 940 may be configured as or otherwise support a means for applying a temporary bond material to a back side of the second volatile memory die based at least in part on bonding the front side of the volatile memory die with the front side of the logic wafer. In some examples, the removal component 945 may be configured as or otherwise support a means for removing a trim portion of the logic wafer based at least in part on applying the temporary bond material to the back side of the second volatile memory die, where removing the trim portion exposes a through-silicon-via (TSV) that extends through the silicon layer of the logic wafer.

In some examples, the formation component 950 may be configured as or otherwise support a means for forming an under-bump metallization (UBM) pad on the logic wafer based at least in part on removing the trim portion of the logic wafer, where the UBM pad is coupled with the conductive bump and the TSV.

In some examples, the described functionality of the manufacturing system 920, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the manufacturing system 920, or various components thereof, may be implemented at least in part by instructions (e.g., stored in memory, non-transitory computer-readable medium) executable by such at least one processor.

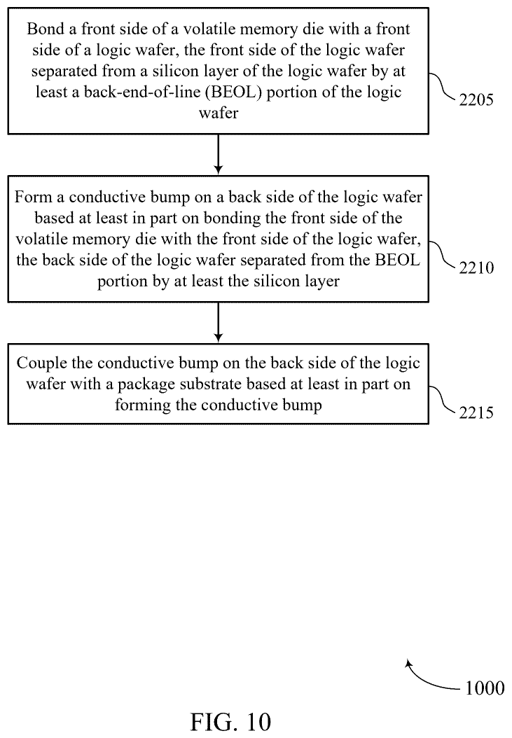

FIG. 10 shows a flowchart illustrating a method 1000 that supports front-to-front bonding in a stacked memory system in accordance with examples as disclosed herein. The operations of method 1000 may be implemented by a manufacturing system or its components as described herein. For example, the operations of method 1000 may be performed by a manufacturing system as described with reference to FIGS. 1 through 9. In some examples, a manufacturing system may execute a set of instructions to control the functional elements of the device to perform the described functions. Additionally, or alternatively, the manufacturing system may perform aspects of the described functions using special-purpose hardware.

At 1005, the method may include bonding a front side of a volatile memory die with a front side of a logic wafer, the front side of the logic wafer separated from a silicon layer of the logic wafer by at least a back-end-of-line (BEOL) portion of the logic wafer. In some examples, aspects of the operations of 1005 may be performed by a bonding component 925 as described with reference to FIG. 9.

At 1010, the method may include forming a conductive bump on a back side of the logic wafer based at least in part on bonding the front side of the volatile memory die with the front side of the logic wafer, the back side of the logic wafer separated from the BEOL portion by at least the silicon layer. In some examples, aspects of the operations of 1010 may be performed by a deposition component 930 as described with reference to FIG. 9.

At 1015, the method may include coupling the conductive bump on the back side of the logic wafer with a package substrate based at least in part on forming the conductive bump. In some examples, aspects of the operations of 1015 may be performed by a coupling component 935 as described with reference to FIG. 9.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for bonding a front side of a volatile memory die with a front side of a logic wafer, the front side of the logic wafer separated from a silicon layer of the logic wafer by at least a back-end-of-line (BEOL) portion of the logic wafer; forming a conductive bump on a back side of the logic wafer based at least in part on bonding the front side of the volatile memory die with the front side of the logic wafer, the back side of the logic wafer separated from the BEOL portion by at least the silicon layer; and coupling the conductive bump on the back side of the logic wafer with a package substrate based at least in part on forming the conductive bump.

Aspect 2: The method, apparatus, or non-transitory computer-readable medium of aspect 1, further including operations, features, circuitry, logic, means, or instructions, or any combination thereof for applying a temporary bond material to a back side of the volatile memory die based at least in part on bonding the front side of the volatile memory die with the front side of the logic wafer and removing a trim portion of the logic wafer based at least in part on applying the temporary bond material, where removing the trim portion exposes a through-silicon-via (TSV) that extends through the silicon layer of the logic wafer.

Aspect 3: The method, apparatus, or non-transitory computer-readable medium of aspect 2, further including operations, features, circuitry, logic, means, or instructions, or any combination thereof for forming an under-bump metallization (UBM) pad on the logic wafer based at least in part on removing the trim portion of the logic wafer, where the UBM pad is coupled with the conductive bump and the TSV.

Aspect 4: The method, apparatus, or non-transitory computer-readable medium of any of aspects 2 through 3, further including operations, features, circuitry, logic, means, or instructions, or any combination thereof for depositing a mold material over the volatile memory die, where the temporary bond material is applied based at least in part on depositing the mold material.

Aspect 5: The method, apparatus, or non-transitory computer-readable medium of aspect 4, further including operations, features, circuitry, logic, means, or instructions, or any combination thereof for removing a trim portion of the mold material, where removing the trim portion exposes a back side of the volatile memory die, and where the temporary bond material is applied based at least in part on removing the trim portion of the mold material.

Aspect 6: The method, apparatus, or non-transitory computer-readable medium of any of aspects 1 through 5, further including operations, features, circuitry, logic, means, or instructions, or any combination thereof for bonding a back side of the volatile memory die with a front side of a second volatile memory die, where the front side of the volatile memory die is bonded with the front side of the logic wafer after bonding the back side of the volatile memory die with the front side of the second volatile memory die.

Aspect 7: The method, apparatus, or non-transitory computer-readable medium of aspect 6, further including operations, features, circuitry, logic, means, or instructions, or any combination thereof for applying a temporary bond material to a back side of the second volatile memory die based at least in part on bonding the front side of the volatile memory die with the front side of the logic wafer and removing a trim portion of the logic wafer based at least in part on applying the temporary bond material to the back side of the second volatile memory die, where removing the trim portion exposes a through-silicon-via (TSV) that extends through the silicon layer of the logic wafer.

Aspect 8: The method, apparatus, or non-transitory computer-readable medium of aspect 7, further including operations, features, circuitry, logic, means, or instructions, or any combination thereof for forming an under-bump metallization (UBM) pad on the logic wafer based at least in part on removing the trim portion of the logic wafer, where the UBM pad is coupled with the conductive bump and the TSV.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a package substrate; a volatile memory die including a front side that is separated from a silicon layer of the volatile memory die by at least a back-end-of-line (BEOL) portion of the volatile memory die; and a logic die including: a front side that is bonded with the front side of the volatile memory die and that is separated from a silicon layer of the logic die by at least a BEOL portion of the logic die; a back side that is separated from the BEOL portion of the logic die by at least the silicon layer of the logic die; and a conductive bump coupled with the back side of the logic die and with the package substrate.

Aspect 10: The apparatus of aspect 9, further including: a second volatile memory die including a front side that is separated from a silicon layer of the second volatile memory die by at least a BEOL portion of the second volatile memory die, where the front side of the logic die is bonded with the front side of the second volatile memory die.

Aspect 11: The apparatus of any of aspects 9 through 10, further including: a second volatile memory die including a front side that is separated from a silicon layer of the second volatile memory die by at least a BEOL portion of the second volatile memory die, where a back side of the volatile memory die is bonded with the front side of the second volatile memory die.

Aspect 12: The apparatus of aspect 11, further including: a through-silicon-via (TSV) that extends through the silicon layer of the volatile memory die and that couples the volatile memory die with the second volatile memory die.

Aspect 13: The apparatus of any of aspects 9 through 12, further including: a through-silicon-via (TSV) that extends through the silicon layer of the logic die and that couples the volatile memory die with the conductive bump.

Aspect 14: The apparatus of any of aspects 9 through 13, further including: a die-interface bond pad disposed on the front side of the logic die and coupled with a die-interface bond pad disposed on the front side of the volatile memory die.

Aspect 15: The apparatus of aspect 14, further including: an oxide layer physically positioned between the BEOL portion of the volatile memory die and the front side of the volatile memory die; and a via that extends through the oxide layer and that couples the die-interface bond pad of the volatile memory die with the BEOL portion of the volatile memory die.

An apparatus is described. The following provides an overview of aspects of the apparatus as described herein:

Aspect 16: An apparatus, including: a first volatile memory die; a logic die including a conductive bump that is coupled with a package substrate; and a second volatile memory die physically positioned between the first volatile memory die and the logic die and including: a back side bonded with a front side of the first volatile memory die; a front side bonded with a front side of the logic die; and a through-silicon-via (TSV) that couples the first volatile memory die with the logic die.

Aspect 17: The apparatus of aspect 16, further including: a first die-interface bond pad of the first volatile memory die coupled with a die-interface bond pad of the logic die; and a second die-interface bond pad of the first volatile memory die coupled with a die-interface bond pad of the second volatile memory die.

Aspect 18: The apparatus of aspect 17, where the TSV couples the first die-interface bond pad of the first volatile memory die with the second die-interface bond pad of the second volatile memory die.

Aspect 19: The apparatus of any of aspects 16 through 18, where the conductive bump is on a back side of the logic die, the apparatus further including: a through-silicon-via (TSV), of the logic die, that couples the conductive bump with the TSV of the second volatile memory die.

Aspect 20: The apparatus of any of aspects 16 through 19, further including: a third volatile memory die including a front side bonded with a front side of the logic die.

Aspect 21: The apparatus of aspect 20, further including: a fourth volatile memory die including a front side bonded with a back side of the third volatile memory die.

Aspect 22: The apparatus of any of aspects 16 through 21, where a back-end-of-line (BEOL) portion is physically positioned between the front side of the first volatile memory die and a silicon layer of the first volatile memory die, and the silicon layer is physically positioned between the BEOL portion and the back side of the first volatile memory die.

Aspect 23: The apparatus of aspect 22, where the TSV of the first volatile memory die extends through the silicon layer of the first volatile memory die.

Aspect 24: The method, apparatus, or non-transitory computer-readable medium of aspect 6, further including operations, features, circuitry, logic, means, or instructions, or any combination thereof for using the logic wafer as a base for bonding the back side of the volatile memory die with the front side of the second volatile memory die.

Aspect 25: The method, apparatus, or non-transitory computer-readable medium of any of aspects 1 through 8, wherein the front side of the volatile memory die is bonded with a front side of a logic wafer via chip-to-wafer bonding, stack-to-wafer bonding, or wafer-to-wafer bonding.

Aspect 26: The method, apparatus, or non-transitory computer-readable medium of any of aspects 1 through 8, further including operations, features, circuitry, logic, means, or instructions, or any combination thereof for forming a die-interface pad on top of the BEOL portion of the logic wafer.

Aspect 27: The apparatus of aspect 5, wherein an end of the TSV closest to the conductive bump has a smaller radius than an end of the TSV farthest from the conductive bump.

Aspect 28: The apparatus of aspect 9, further including: a through-silicon-via (TSV) that extends through the silicon layer of the logic die and that is coupled with the conductive bump.

Aspect 29: The apparatus of aspect 9, further including: a first die-interface bond pad, of the volatile memory die, that is coupled with an aluminum pad of the volatile memory die; and a second die-interface bond pad, of the logic die, that is coupled with an aluminum pad of the logic die and that is hybrid bonded with the first die-interface bond pad of the volatile memory die.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a.” “at least one.” “one or more.” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components.” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a package substrate;
a volatile memory die comprising a front side that is separated from a silicon layer of the volatile memory die by at least a back-end-of-line (BEOL) portion of the volatile memory die; and
a logic die comprising:
a front side that is bonded with the front side of the volatile memory die and that is separated from a silicon layer of the logic die by at least a BEOL portion of the logic die;
a back side that is separated from the BEOL portion of the logic die by at least the silicon layer of the logic die; and
a conductive bump coupled with the back side of the logic die and with the package substrate.

2. The apparatus of claim 1, further comprising:
a second volatile memory die comprising a front side that is separated from a silicon layer of the second volatile memory die by at least a BEOL portion of the second volatile memory die, wherein the front side of the logic die is bonded with the front side of the second volatile memory die.

3. The apparatus of claim 1, further comprising:
a second volatile memory die comprising a front side that is separated from a silicon layer of the second volatile memory die by at least a BEOL portion of the second volatile memory die, wherein a back side of the volatile memory die is bonded with the front side of the second volatile memory die.

4. The apparatus of claim 3, further comprising:
a through-silicon-via (TSV) that extends through the silicon layer of the volatile memory die and that couples the volatile memory die with the second volatile memory die.

5. The apparatus of claim 1, further comprising:
a through-silicon-via (TSV) that extends through the silicon layer of the logic die and that couples the volatile memory die with the conductive bump.

6. The apparatus of claim 5, wherein an end of the TSV closest to the conductive bump has a smaller radius than an end of the TSV farthest from the conductive bump.

7. The apparatus of claim 1, further comprising:
a die-interface bond pad disposed on the front side of the logic die and coupled with a die-interface bond pad disposed on the front side of the volatile memory die.

8. The apparatus of claim 7, further comprising:
an oxide layer physically positioned between the BEOL portion of the volatile memory die and the front side of the volatile memory die; and
a via that extends through the oxide layer and that couples the die-interface bond pad of the volatile memory die with the BEOL portion of the volatile memory die.

9. The apparatus of claim 1, further comprising:
a through-silicon-via (TSV) that extends through the silicon layer of the logic die and that is coupled with the conductive bump.

10. The apparatus of claim 1, further comprising:
a first die-interface bond pad, of the volatile memory die, that is coupled with an aluminum pad of the volatile memory die; and
a second die-interface bond pad, of the logic die, that is coupled with an aluminum pad of the logic die and that is hybrid bonded with the first die-interface bond pad of the volatile memory die.

11. An apparatus, comprising:
a first volatile memory die;
a logic die comprising a conductive bump that is coupled with a package substrate; and
a second volatile memory die physically positioned between the first volatile memory die and the logic die and comprising:
a back side bonded with a front side of the first volatile memory die;
a front side bonded with a front side of the logic die; and
a through-silicon-via (TSV) that couples the first volatile memory die with the logic die.

12. The apparatus of claim 11, further comprising:
a first die-interface bond pad of the first volatile memory die coupled with a die-interface bond pad of the logic die; and
a second die-interface bond pad of the first volatile memory die coupled with a die-interface bond pad of the second volatile memory die.

13. The apparatus of claim 12, wherein the TSV couples the first die-interface bond pad of the first volatile memory die with the second die-interface bond pad of the second volatile memory die.

14. The apparatus of claim 11, wherein the conductive bump is on a back side of the logic die, the apparatus further comprising:
a through-silicon-via (TSV), of the logic die, that couples the conductive bump with the TSV of the second volatile memory die.

15. The apparatus of claim 11, further comprising:
a third volatile memory die comprising a front side bonded with a front side of the logic die.

16. The apparatus of claim 15, further comprising:
a fourth volatile memory die comprising a front side bonded with a back side of the third volatile memory die.

17. The apparatus of claim 11, wherein:
a back-end-of-line (BEOL) portion is physically positioned between the front side of the first volatile memory die and a silicon layer of the first volatile memory die, and
the silicon layer is physically positioned between the BEOL portion and the back side of the first volatile memory die.

18. The apparatus of claim 17, wherein the TSV of the first volatile memory die extends through the silicon layer of the first volatile memory die.

19. A method, comprising:
bonding a front side of a volatile memory die with a front side of a logic wafer, the front side of the logic wafer separated from a silicon layer of the logic wafer by at least a back-end-of-line (BEOL) portion of the logic wafer;
forming a conductive bump on a back side of the logic wafer based at least in part on bonding the front side of the volatile memory die with the front side of the logic wafer, the back side of the logic wafer separated from the BEOL portion by at least the silicon layer; and
coupling the conductive bump on the back side of the logic wafer with a package substrate based at least in part on forming the conductive bump.

20. The method of claim 19, further comprising:
applying a temporary bond material to a back side of the volatile memory die based at least in part on bonding the front side of the volatile memory die with the front side of the logic wafer; and
removing a trim portion of the logic wafer based at least in part on applying the temporary bond material, wherein removing the trim portion exposes a through-silicon-via (TSV) that extends through the silicon layer of the logic wafer.

21. The method of claim 20, further comprising:
forming an under-bump metallization (UBM) pad on the logic wafer based at least in part on removing the trim portion of the logic wafer, wherein the UBM pad is coupled with the conductive bump and the TSV.

22. The method of claim 20, further comprising:
depositing a mold material over the volatile memory die, wherein the temporary bond material is applied based at least in part on depositing the mold material.

23. The method of claim 22, further comprising:
removing a trim portion of the mold material, wherein removing the trim portion exposes a back side of the volatile memory die, and wherein the temporary bond material is applied based at least in part on removing the trim portion of the mold material.

24. The method of claim 19, further comprising:
bonding a back side of the volatile memory die with a front side of a second volatile memory die, wherein the front side of the volatile memory die is bonded with the front side of the logic wafer after bonding the back side of the volatile memory die with the front side of the second volatile memory die.

25. The method of claim 24, further comprising:
using the logic wafer as a base for bonding the back side of the volatile memory die with the front side of the second volatile memory die.

26. The method of claim 24, further comprising:
applying a temporary bond material to a back side of the second volatile memory die based at least in part on bonding the front side of the volatile memory die with the front side of the logic wafer; and
removing a trim portion of the logic wafer based at least in part on applying the temporary bond material to the back side of the second volatile memory die, wherein removing the trim portion exposes a through-silicon-via (TSV) that extends through the silicon layer of the logic wafer.

27. The method of claim 26, further comprising:
forming an under-bump metallization (UBM) pad on the logic wafer based at least in part on removing the trim portion of the logic wafer, wherein the UBM pad is coupled with the conductive bump and the TSV.

28. The method of claim 19, wherein the front side of the volatile memory die is bonded with a front side of a logic wafer via chip-to-wafer bonding, stack-to-wafer bonding, or wafer-to-wafer bonding.

29. The method of claim 19, further comprising:
forming a die-interface pad on top of the BEOL portion of the logic wafer.
